(19) United States
(12) Patent Application Publication
(10) Pub. No.: US 2022/0252971 A1
(43) Pub. Date: Aug. 11, 2022

(54) Extreme Ultraviolet Mask Blank Structure

(71) Applicant: Applied Materials, Inc., Santa Clara, CA (US)

(72) Inventors: Shuwei Liu, Singapore (SG); Shiyu Liu, Singapore (SG); Vibhu Jindal, San Jose, CA (US)

(73) Assignee: Applied Materials, Inc., Santa Clara, CA (US)

(21) Appl. No.: 17/666,733

(22) Filed: Feb. 8, 2022

Related U.S. Application Data
(60) Provisional application No. 63/147,552, filed on Feb. 9, 2021.

(51) Int. Cl. G03F 1/24

(52) U.S. Cl. CPC G03F 1/24

(57) ABSTRACT

Extreme ultraviolet (EUV) mask blanks, methods for their manufacture and production systems therefor are disclosed. The EUV mask blanks comprise a substrate; a multilayer stack of reflective layers on the substrate; a capping layer on the multilayer stack of reflecting layers; an absorber layer on the capping layer, the absorber layer comprising an antimony-containing material; and a trilayer on the second side of the substrate, the trilayer including a first layer on the second side of the substrate, a second layer on the first layer and a third layer on the second layer. In some embodiments, separately from or in addition to the trilayer the mask blank includes an etch stop layer between the absorber layer and the capping layer, and there is a hard mask layer on the absorber layer.

### CROSS-REFERENCE TO RELATED APPLICATIONS

This application claims priority to U.S. Provisional Application No. 63/147,552, filed Feb. 9, 2021, the entire disclosure of which is hereby incorporated by reference herein.

### TECHNICAL FIELD

The present disclosure relates generally to extreme ultraviolet lithography, and more particularly, extreme ultraviolet mask blanks which exhibit improved performance.

### BACKGROUND

Extreme ultraviolet (EUV) lithography, also known as soft x-ray projection lithography, is used for the manufacture of 0.0135 micron and smaller minimum feature size semiconductor devices. However, extreme ultraviolet light, which is generally in the 5 to 100 nanometer wavelength range, is strongly absorbed in virtually all materials. For that reason, extreme ultraviolet systems work by reflection rather than by transmission of light. Through the use of a series of mirrors, or lens elements, and a reflective element, or mask blank, coated with a non-reflective absorber mask pattern, the patterned actinic light is reflected onto a resist-coated semiconductor substrate.

The lens elements and mask blanks of extreme ultraviolet lithography systems are coated with reflective multilayer coatings of materials such as molybdenum and silicon. Reflection values of approximately 65% per lens element, or mask blank, have been obtained by using substrates that are coated with multilayer coatings that strongly reflect light within an extremely narrow ultraviolet bandpass, for example, 12.5 to 14.5 nanometer bandpass for 13.5 nanometer ultraviolet light. EUV mask blanks are utilized to form EUV reflective masks.

FIG. 1 shows a conventional EUV reflective mask 10, which is formed from an EUV mask blank, which includes a reflective multilayer stack 12 on a substrate 14, which reflects EUV radiation at unmasked portions by Bragg interference. Masked (non-reflective) areas 16 of the conventional EUV reflective mask 10 are formed by etching buffer layer 18 and absorbing layer 20. A capping layer 22 is formed over the reflective multilayer stack 12 and protects the reflective multilayer stack 12 during the etching process. As will be discussed further below, EUV mask blanks are made on a low thermal expansion material substrate coated with multilayers, a capping layer and an absorber layer, which is then etched to provide the masked (non-reflective) areas 16 and reflective areas 24.

During manufacture of EUV mask blanks, a hard mask is formed over an absorber layer. A reflective mask having a mask pattern is formed from an EUV mask blank including the hard mask layer by etching and other processes. Certain properties of EUV mask blanks such as flatness, scratch resistance of backside layers blanks and improved performance during etching are desired to improve performance of masks and production of masks from mask blanks.

### SUMMARY

A first aspect of the disclosure is directed to extreme an ultraviolet (EUV) mask blank. According to an embodiment, an EUV mask blank comprises a substrate including a first side and a second side opposite the first side; a multilayer stack on the first side of the substrate which reflects EUV radiation, the multilayer stack comprising a plurality of reflective layer pairs; a capping layer on the multilayer stack of reflecting layers; an absorber layer on the capping layer; and a trilayer on the second side of the substrate, the trilayer including a first layer on the second side of the substrate, a second layer on the first layer and a third layer on the second layer.

Another aspect of the disclosure is directed to method of manufacturing an extreme ultraviolet (EUV) mask blank. According to an embodiment, a method comprises forming on a first side of a substrate a multilayer stack which reflects EUV radiation, the multilayer stack comprising a plurality of reflective layer pairs, the substrate including a second side opposite the first side; forming a capping layer on the multilayer stack; forming an absorber layer on the capping layer; and forming on the second side of the substrate a trilayer including a first layer on the second side of the substrate, a second layer on the first layer and a third layer on the second layer.

Another aspect of the disclosure pertains to extreme ultraviolet (EUV) mask blank comprising a substrate including a first side and a second side opposite the first side; a multilayer stack on the first side of the substrate which reflects EUV radiation, the multilayer stack comprising a plurality of reflective layer pairs; a capping layer on the multilayer stack; an etch stop layer on the capping layer; an absorber layer on the etch stop layer; and a hard mask layer on the absorber layer.

Another aspect of the disclosure pertains to a method of manufacturing an extreme ultraviolet (EUV) mask blank comprising forming on a first side of a substrate a multilayer stack which reflects EUV radiation, the multilayer stack comprising a plurality of reflective layer pairs, the substrate including a second side opposite the first side; forming a capping layer on the multilayer stack; forming an etch stop layer on the capping layer; forming an absorber layer on the etch stop layer; and forming a hard mask layer on the absorber layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 schematically illustrates a background art EUV reflective mask employing a conventional absorber;

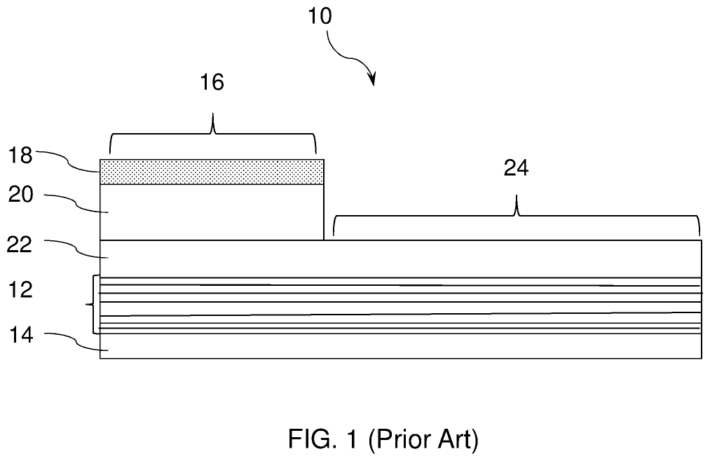

FIG. 2 schematically illustrates an embodiment of an extreme ultraviolet lithography system;

FIG. 3 illustrates an embodiment of an extreme ultraviolet reflective element production system;

FIG. 4 illustrates an embodiment of an extreme ultraviolet reflective element such as an EUV mask blank; and

FIG. 5 illustrates an embodiment of a multi-cathode physical deposition chamber.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “horizontal” as used herein is defined as a plane parallel to the plane or surface of a mask blank, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures.

The term “on” indicates that there is direct contact between elements. The term “directly on” indicates that there is direct contact between elements with no intervening elements.

Those skilled in the art will understand that the use of ordinals such as “first” and “second” to describe process regions do not imply a specific location within the processing chamber, or order of exposure within the processing chamber.

As used in this specification and the appended claims, the term “substrate” refers to a surface, or portion of a surface, upon which a process acts. It will also be understood by those skilled in the art that reference to a substrate refers to only a portion of the substrate, unless the context clearly indicates otherwise. Additionally, reference to depositing on a substrate means both a bare substrate and a substrate with one or more films or features deposited or formed thereon.

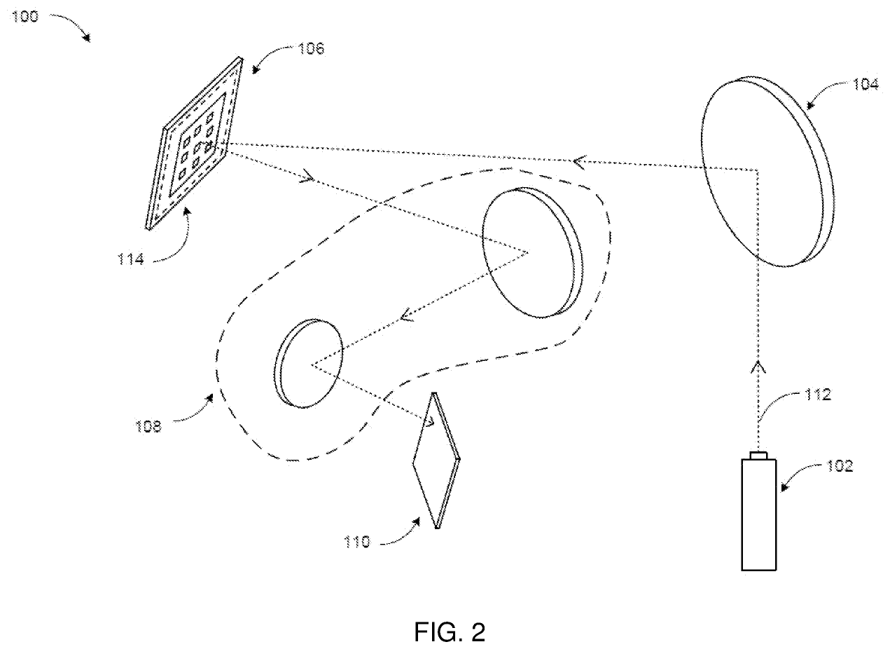

Referring now to FIG. 2, an exemplary embodiment of an extreme ultraviolet lithography system 100 is shown. The extreme ultraviolet lithography system 100 includes an extreme ultraviolet light source 102 for producing extreme ultraviolet light 112, a set of reflective elements, and a target wafer 110. The reflective elements include a condenser 104, an EUV reflective mask 106, an optical reduction assembly 108, a mask blank, a mirror, or a combination thereof.

The extreme ultraviolet light source 102 generates the extreme ultraviolet light 112. The extreme ultraviolet light 112 is electromagnetic radiation having a wavelength in a range of 5 to 50 nanometers (nm). For example, the extreme ultraviolet light source 102 includes a laser, a laser produced plasma, a discharge produced plasma, a free-electron laser, synchrotron radiation, or a combination thereof.

The extreme ultraviolet light source 102 generates the extreme ultraviolet light 112 having a variety of characteristics. The extreme ultraviolet light source 102 produces broadband extreme ultraviolet radiation over a range of wavelengths. For example, the extreme ultraviolet light source 102 generates the extreme ultraviolet light 112 having wavelengths ranging from 5 to 50 nm.

In one or more embodiments, the extreme ultraviolet light source 102 produces the extreme ultraviolet light 112 having a narrow bandwidth. For example, the extreme ultraviolet light source 102 generates the extreme ultraviolet light 112 at 13.5 nm. The center of the wavelength peak is 13.5 nm.

The condenser 104 is an optical unit for reflecting and focusing the extreme ultraviolet light 112. The condenser 104 reflects and concentrates the extreme ultraviolet light 112 from the extreme ultraviolet light source 102 to illuminate the EUV reflective mask 106.

Although the condenser 104 is shown as a single element, it is understood that the condenser 104 in some embodiments includes one or more reflective elements such as concave mirrors, convex mirrors, flat mirrors, or a combination thereof, for reflecting and concentrating the extreme ultraviolet light 112. For example, the condenser 104 in some embodiments is a single concave mirror or an optical assembly having convex, concave, and flat optical elements.

The EUV reflective mask 106 is an extreme ultraviolet reflective element having a mask pattern 114. The EUV reflective mask 106 creates a lithographic pattern to form a circuitry layout to be formed on the target wafer 110. The EUV reflective mask 106 reflects the extreme ultraviolet light 112. The mask pattern 114 defines a portion of a circuitry layout.

The optical reduction assembly 108 is an optical unit for reducing the image of the mask pattern 114. The reflection of the extreme ultraviolet light 112 from the EUV reflective mask 106 is reduced by the optical reduction assembly 108 and reflected on to the target wafer 110. The optical reduction assembly 108 in some embodiments includes mirrors and other optical elements to reduce the size of the image of the mask pattern 114. For example, the optical reduction assembly 108 in some embodiments includes concave mirrors for reflecting and focusing the extreme ultraviolet light 112.

The optical reduction assembly 108 reduces the size of the image of the mask pattern 114 on the target wafer 110. For example, the mask pattern 114 in some embodiments is imaged at a 4:1 ratio by the optical reduction assembly 108 on the target wafer 110 to form the circuitry represented by the mask pattern 114 on the target wafer 110. The extreme ultraviolet light 112 in some embodiments scans the EUV reflective mask 106 synchronously with the target wafer 110 to form the mask pattern 114 on the target wafer 110.

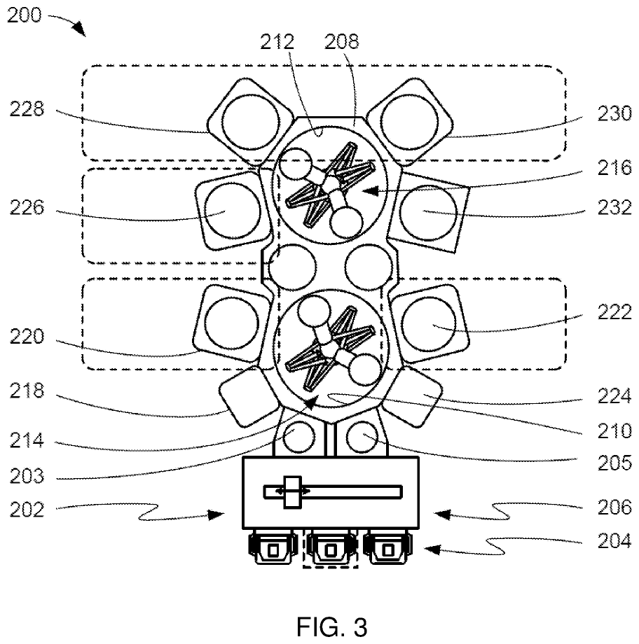

Referring now to FIG. 3, an embodiment of an extreme ultraviolet reflective element production system 200 is shown. The extreme ultraviolet reflective element includes a EUV mask blank 204, an extreme ultraviolet mirror 205, or other reflective element such as an EUV reflective mask 106.

The extreme ultraviolet reflective element production system 200 in some embodiments produces mask blanks, mirrors, or other elements that reflect the extreme ultraviolet light 112 of FIG. 2. The extreme ultraviolet reflective element production system 200 fabricates the reflective elements by applying thin coatings to source substrates 203.

The EUV mask blank 204 is a multilayered structure for forming the EUV reflective mask 106 of FIG. 2. The EUV mask blank 204 in some embodiments is formed using semiconductor fabrication techniques. The EUV reflective mask 106 in some embodiments has the mask pattern 114 of FIG. 2 formed on the EUV mask blank 204 by etching and other processes.

The extreme ultraviolet mirror 205 is a multilayered structure reflective in a range of extreme ultraviolet light. The extreme ultraviolet mirror 205 in some embodiments is formed using semiconductor fabrication techniques. The EUV mask blank 204 and the extreme ultraviolet mirror 205 in some embodiments are similar structures with respect to the layers formed on each element, however, the extreme ultraviolet mirror 205 does not have the mask pattern 114.

The reflective elements are efficient reflectors of the extreme ultraviolet light 112. In an embodiment, the EUV mask blank 204 and the extreme ultraviolet mirror 205 has an extreme ultraviolet reflectivity of greater than 60%. The reflective elements are efficient if they reflect more than 60% of the extreme ultraviolet light 112.

The extreme ultraviolet reflective element production system 200 includes a wafer loading and carrier handling system 202 into which the source substrates 203 are loaded and from which the reflective elements are unloaded. An atmospheric handling system 206 provides access to a wafer handling vacuum chamber 208. The wafer loading and carrier handling system 202 in some embodiments includes substrate transport boxes, loadlocks, and other components to transfer a substrate from atmosphere to vacuum inside the system. Because the EUV mask blank 204 is used to form devices at a very small scale, the source substrates 203 and the EUV mask blank 204 are processed in a vacuum system to prevent contamination and other defects.

The wafer handling vacuum chamber 208 in some embodiments contains two vacuum chambers, a first vacuum chamber 210 and a second vacuum chamber 212. The first vacuum chamber 210 includes a first wafer handling system 214 and the second vacuum chamber 212 includes a second wafer handling system 216. Although the wafer handling vacuum chamber 208 is described with two vacuum chambers, it is understood that the system in some embodiments has any number of vacuum chambers.

The wafer handling vacuum chamber 208 in some embodiments has a plurality of ports around its periphery for attachment of various other systems. The first vacuum chamber 210 has a degas system 218, a first physical vapor deposition system 220, a second physical vapor deposition system 222, and a pre-clean system 224. The degas system 218 is for thermally desorbing moisture from the substrates. The pre-clean system 224 is for cleaning the surfaces of the wafers, mask blanks, mirrors, or other optical components.

The physical vapor deposition systems, such as the first physical vapor deposition system 220 and the second physical vapor deposition system 222, in some embodiments are used to form thin films of conductive materials on the source substrates 203. For example, the physical vapor deposition systems in some embodiments includes vacuum deposition system such as magnetron sputtering systems, ion sputtering systems, pulsed laser deposition, cathode arc deposition, or a combination thereof. The physical vapor deposition systems, such as the magnetron sputtering system, form thin layers on the source substrates 203 including the layers of silicon, metals, alloys, compounds, or a combination thereof.

The physical vapor deposition system forms reflective layers, capping layers, and absorber layers. For example, the physical vapor deposition systems in some embodiments forms layers of silicon, molybdenum, titanium oxide, titanium dioxide, ruthenium oxide, niobium oxide, ruthenium tungsten, ruthenium molybdenum, ruthenium niobium, chromium, antimony, iron, copper, boron, nickel, bismuth, tellurium, hafnium, tantalum, antimony, nitrides, compounds, or a combination thereof. Although some compounds are described as an oxide, it is understood that the compounds in some embodiments include oxides, dioxides, atomic mixtures having oxygen atoms, or a combination thereof.

The second vacuum chamber 212 has a first multi-cathode source 226, a chemical vapor deposition system 228, a cure chamber 230, and an ultra-smooth deposition chamber 232 connected to it. For example, the chemical vapor deposition system 228 in some embodiments includes a flowable chemical vapor deposition system (FCVD), a plasma assisted chemical vapor deposition system (CVD), an aerosol assisted CVD system, a hot filament CVD system, or a similar system. In another example, the chemical vapor deposition system 228, the cure chamber 230, and the ultra-smooth deposition chamber 232 in some embodiments are in a separate system from the extreme ultraviolet reflective element production system 200.

The chemical vapor deposition system 228 in some embodiments forms thin films of material on the source substrates 203. For example, the chemical vapor deposition system 228 in some embodiments is used to form layers of materials on the source substrates 203 including mono-crystalline layers, polycrystalline layers, amorphous layers, epitaxial layers, or a combination thereof. The chemical vapor deposition system 228 in some embodiments forms layers of silicon, silicon oxides, silicon oxycarbide, tantalum, tellurium, antimony, hafnium, iron, copper, boron, nickel, tungsten, bismuth silicon carbide, silicon nitride, titanium nitride, metals, alloys, and other materials suitable for chemical vapor deposition. For example, the chemical vapor deposition system in some embodiments forms planarization layers.

The first wafer handling system 214 is capable of moving the source substrates 203 between the atmospheric handling system 206 and the various systems around the periphery of the first vacuum chamber 210 in a continuous vacuum. The second wafer handling system 216 is capable of moving the source substrates 203 around the second vacuum chamber 212 while maintaining the source substrates 203 in a continuous vacuum. The extreme ultraviolet reflective element production system 200 in some embodiments transfers the source substrates 203 and the EUV mask blank 204 between the first wafer handling system 214, the second wafer handling system 216 in a continuous vacuum.

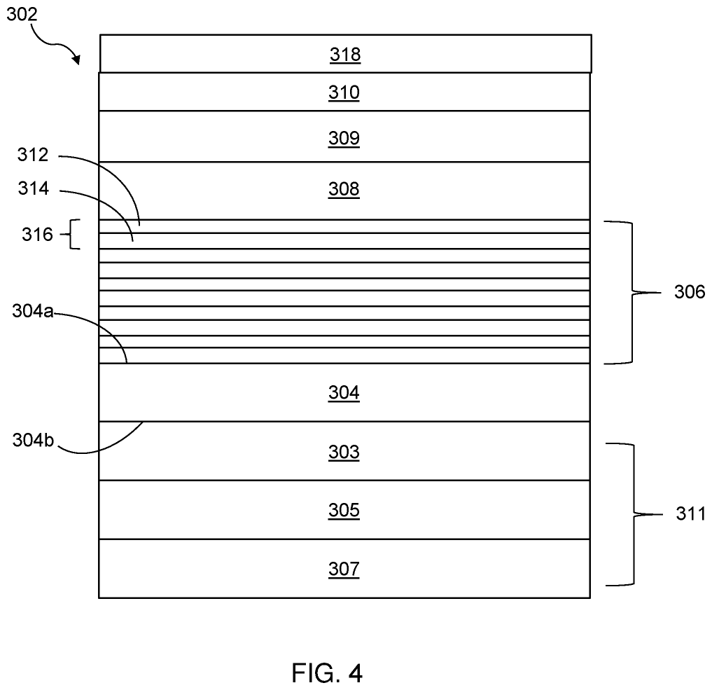

Referring now to FIG. 4, an embodiment of an extreme ultraviolet reflective element 302 is shown. In one or more embodiments, the extreme ultraviolet reflective element 302 is the EUV mask blank 204 of FIG. 3 or the extreme ultraviolet mirror 205 of FIG. 3. The EUV mask blank 204 and the extreme ultraviolet mirror 205 are structures for reflecting the extreme ultraviolet light 112 of FIG. 2. The EUV mask blank 204 in some embodiments is used to form the EUV reflective mask 106 shown in FIG. 2.

The extreme ultraviolet reflective element 302 includes a substrate 304, a multilayer stack 306 of reflective layers, and a capping layer 308. In one or more embodiments, the extreme ultraviolet mirror 205 is used to form reflecting structures for use in the condenser 104 of FIG. 2 or the optical reduction assembly 108 of FIG. 2.

The extreme ultraviolet reflective element 302, which in some embodiments is a EUV mask blank 204, includes the substrate 304, the multilayer stack 306 of reflective layers, the capping layer 308, an absorber layer 310, and a hard mask layer. The extreme ultraviolet reflective element 302 in some embodiments is a EUV mask blank 204, which is used to form the EUV reflective mask 106 of FIG. 2 by patterning the absorber layer 310 with the layout of the circuitry required.

In the following sections, the term for the EUV mask blank 204 is used interchangeably with the term of the extreme ultraviolet mirror 205 for simplicity. In one or more embodiments, the EUV mask blank 204 includes the components of the extreme ultraviolet mirror 205 with the absorber layer 310 added in addition to form the mask pattern 114 of FIG. 2.

The EUV mask blank 204 is an optically flat structure used for forming the EUV reflective mask 106 having the mask pattern 114. In one or more embodiments, the reflective surface of the EUV mask blank 204 forms a flat focal plane for reflecting the incident light, such as the extreme ultraviolet light 112 of FIG. 2.

The substrate 304 is an element for providing structural support to the extreme ultraviolet reflective element 302. In one or more embodiments, the substrate 304 is made from a material having a low coefficient of thermal expansion (CTE) to provide stability during temperature changes. In one or more embodiments, the substrate 304 has properties such as stability against mechanical cycling, thermal cycling, crystal formation, or a combination thereof. The substrate 304 according to one or more embodiments is formed from a material such as silicon, glass, oxides, ceramics, glass ceramics, or a combination thereof. The substrate includes a first side 304a and a second side 304b opposite the first side 304a. The second side 304b may also be referred to as a backside of the substrate 304.

The multilayer stack 306 is on the first side 304a of the substrate and is a structure that is reflective to the extreme ultraviolet light 112. The multilayer stack 306 includes alternating reflective layers of a first reflective layer 312 and a second reflective layer 314.

The first reflective layer 312 and the second reflective layer 314 form a reflective pair 316. In a non-limiting embodiment, the multilayer stack 306 includes a range of 20-60 of the reflective pairs 316 for a total of up to 120 reflective layers.

The first reflective layer 312 and the second reflective layer 314 in some embodiments are formed from a variety of materials. In an embodiment, the first reflective layer 312 and the second reflective layer 314 are formed from silicon and molybdenum, respectively. Although the layers are shown as silicon and molybdenum, it is understood that the alternating layers in some embodiments are formed from other materials or have other internal structures.

The first reflective layer 312 and the second reflective layer 314 in some embodiments have a variety of structures. In an embodiment, both the first reflective layer 312 and the second reflective layer 314 are formed with a single layer, multiple layers, a divided layer structure, non-uniform structures, or a combination thereof.

Because most materials absorb light at extreme ultraviolet wavelengths, the optical elements used are reflective instead of the transmissive as used in other lithography systems. The multilayer stack 306 forms a reflective structure by having alternating thin layers of materials with different optical properties to create a Bragg reflector or mirror.

In an embodiment, each of the alternating layers has dissimilar optical constants for the extreme ultraviolet light 112. The alternating layers provide a resonant reflectivity when the period of the thickness of the alternating layers is one half the wavelength of the extreme ultraviolet light 112. In an embodiment, for the extreme ultraviolet light 112 at a wavelength of 13 nm, the alternating layers are about 6.5 nm thick. It is understood that the sizes and dimensions provided are within normal engineering tolerances for typical elements.

The multilayer stack 306 in some embodiments is formed in a variety of ways. In an embodiment, the first reflective layer 312 and the second reflective layer 314 are formed with magnetron sputtering, ion sputtering systems, pulsed laser deposition, cathode arc deposition, or a combination thereof.

In an illustrative embodiment, the multilayer stack 306 is formed using a physical vapor deposition technique, such as magnetron sputtering. In an embodiment, the first reflective layer 312 and the second reflective layer 314 of the multilayer stack 306 have the characteristics of being formed by the magnetron sputtering technique including precise thickness, low roughness, and clean interfaces between the layers. In an embodiment, the first reflective layer 312 and the second reflective layer 314 of the multilayer stack 306 have the characteristics of being formed by the physical vapor deposition including precise thickness, low roughness, and clean interfaces between the layers.

The physical dimensions of the layers of the multilayer stack 306 formed using the physical vapor deposition technique in some embodiments is precisely controlled to increase reflectivity. In an embodiment, the first reflective layer 312, such as a layer of silicon, has a thickness of 4.1 nm. The second reflective layer 314, such as a layer of molybdenum, has a thickness of 2.8 nm. The thickness of the layers dictates the peak reflectivity wavelength of the extreme ultraviolet reflective element. If the thickness of the layers is incorrect, the reflectivity at the desired wavelength 13.5 nm in some embodiments is reduced.

In an embodiment, the multilayer stack 306 has a reflectivity of greater than 60%. In an embodiment, the multilayer stack 306 formed using physical vapor deposition has a reflectivity in a range of 66%-67%. In one or more embodiments, forming the capping layer 308 over the multilayer stack 306 formed with harder materials improves reflectivity. In some embodiments, reflectivity greater than 70% is achieved using low roughness layers, clean interfaces between layers, improved layer materials, or a combination thereof.

In one or more embodiments, the capping layer 308 is a protective layer allowing the transmission of the extreme ultraviolet light 112. In an embodiment, the capping layer 308 is formed directly on the multilayer stack 306. In one or more embodiments, the capping layer 308 protects the multilayer stack 306 from contaminants and mechanical damage. In one embodiment, the multilayer stack 306 is sensitive to contamination by oxygen, tantalum, hydrotantalums, or a combination thereof. The capping layer 308 according to an embodiment interacts with the contaminants to neutralize them.

In one or more embodiments, the capping layer 308 is an optically uniform structure that is transparent to the extreme ultraviolet light 112. The extreme ultraviolet light 112 passes through the capping layer 308 to reflect off of the multilayer stack 306. In one or more embodiments, the capping layer 308 has a total reflectivity loss of 1% to 2%. In one or more embodiments, each of the different materials has a different reflectivity loss depending on thickness, but all of them will be in a range of 1% to 2%.

In one or more embodiments, the capping layer 308 has a smooth surface. For example, the surface of the capping layer 308 in some embodiments has a roughness of less than 0.2 nm RMS (root mean square measure). In another example, the surface of the capping layer 308 has a roughness of 0.08 nm RMS for a length in a range of 1/100 nm and 1/1 μm. The RMS roughness will vary depending on the range it is measured over. For the specific range of 100 nm to 1 micron that roughness is 0.08 nm or less. Over a larger range the roughness will be higher.

The capping layer 308 in some embodiments is formed in a variety of methods. In an embodiment, the capping layer 308 is formed on or directly on the multilayer stack 306 with magnetron sputtering, ion sputtering systems, ion beam deposition, electron beam evaporation, radio frequency (RF) sputtering, atomic layer deposition (ALD), pulsed laser deposition, cathode arc deposition, or a combination thereof. In one or more embodiments, the capping layer 308 has the physical characteristics of being formed by the magnetron sputtering technique including precise thickness, low roughness, and clean interfaces between the layers. In an embodiment, the capping layer 308 has the physical characteristics of being formed by the physical vapor deposition including precise thickness, low roughness, and clean interfaces between the layers.

In one or more embodiments, the capping layer 308 is formed from a variety of materials having a hardness sufficient to resist erosion during cleaning. In one embodiment, ruthenium is used as a capping layer material because it is a good etch stop and is relatively inert under the operating conditions. However, it is understood that other materials in some embodiments are used to form the capping layer 308. In specific embodiments, the capping layer 308 has a thickness in a range of 2.5 and 5.0 nm.

In one or more embodiments, the absorber layer 310 is a layer that absorbs the extreme ultraviolet light 112. In an embodiment, the absorber layer 310 is used to form the pattern on the EUV reflective mask 106 by providing areas that do not reflect the extreme ultraviolet light 112. The absorber layer 310, according to one or more embodiments, comprises a material having a high absorption coefficient for a particular frequency of the extreme ultraviolet light 112, such as about 13.5 nm. In an embodiment, the absorber layer 310 is formed directly on the capping layer 308, and the absorber layer 310 is etched using a photolithography process to form the pattern of the EUV reflective mask 106.

According to one or more embodiments, the extreme ultraviolet reflective element 302, such as the extreme ultraviolet mirror 205, is formed with the substrate 304, the multilayer stack 306, and the capping layer 308. The extreme ultraviolet mirror 205 has an optically flat surface and in some embodiments efficiently and uniformly reflects the extreme ultraviolet light 112.

According to one or more embodiments, the extreme ultraviolet reflective element 302, such as the EUV mask blank 204, is formed with the substrate 304, the multilayer stack 306, the capping layer 308, the absorber layer 310, and the hard mask layer 318. The mask blank 204 has an optically flat surface and in some embodiments efficiently and uniformly reflects the extreme ultraviolet light 112. In an embodiment, the mask pattern 114 is formed with the absorber layer 310 of the EUV mask blank 204.

According to one or more embodiments, forming the absorber layer 310 over the capping layer 308 increases reliability of the EUV reflective mask 106. The capping layer 308 in some embodiments acts as an etch stop layer for the absorber layer 310. When the mask pattern 114 of FIG. 2 is etched into the absorber layer 310, the capping layer 308 beneath the absorber layer 310 stops the etching action to protect the multilayer stack 306. In one or more embodiments, the absorber layer 310 is etch selective to the capping layer 308. In some embodiments, the capping layer 308 comprises ruthenium, and the absorber layer 310 is etch selective to ruthenium.

In one or more embodiments, there is an etch stop layer 309 on the capping layer 308 and the absorber layer 310 is on the etch stop layer 309. The etch stop layer 309 serves as protection for the capping layer 308 during etching. In one or more embodiments, the etch stop layer comprises a material selected from the group consisting of CrN, CrₓO_{y}N_{z}, SiₓN_{y}, TaNi, TaRu and TaCu. In the embodiment shown, the etch stop layer 309 is on the capping layer 308 and beneath the absorber layer 310.

In an embodiment, the absorber layer 310 comprises a material selected from the group consisting of TaSb, TaCu, TaRu, TaRuSb, TaNi, TaIr, TaIrSb, TaPt, TaMo, TaNb, TaPd, TeGeSbC, SbN, RuSb, IrSb, CSb, SbTe, SbPt, SbNb, SbPd, MoN, MoPt, MoNb, TeGe, BiFe, BNi, CuHf, IrAl, IrMo, TeNi, TeAl, TeCu, TeFe, RuMo, RuSi, RuIr, TaRuIr, RuN, RuPd, RuPt, RuNb, NbPd and oxides and nitrides thereof. Some absorber layer materials, for example, antimony-containing absorber layer materials present etch selectivity issues during the manufacture of EUV reflective elements with respect to the absorber layer 310.

In one or more embodiments, the hard mask layer 318 has an etch rate and the absorber layer 310 has an etch rate such that there is an etch selectivity of the hard mask layer 318 to the absorber layer 310 is in a range of from 3:1 to 50:1, for example, of from 4:1 to 40:1, or of from 5:1 to 50:1, or of from 5:1 to 40:1 or of from 5:1 to 30, or of from 10:1 to 50:1, or of from 10:1 to 40:1, or of from 10:1 to 30:1. According to one or more embodiments, the etch rates provided immediately above are with reference to CI and/or F related etch chemistries. In one or more embodiments, the absorber layer 310 has a thickness in a range of from 20 nm to 60 nm, for example, of from 30 nm to 45 nm, and the hard mask layer 318 has a thickness in a range of from 1 nm to 20 nm, for example of from 2 nm to 9 nm. In one or more embodiments, the hard mask layer 318 comprises a material selected from the group consisting of selected from the group consisting of CrN, CrₓO_{y}N_{z}, SiₓN_{y}, TaNi, TaRu, and TaCu. In some embodiments, hard mask layer 318 and the etch stop layer 309 comprise the same material. In some embodiments, the hard mask layer 318 and the etch stop layer 309 comprise different materials.

In some embodiments, the absorber layer 310 has a thickness of less than about 75 nm, including less than about 65 nm, less than about 55 nm, or less than about 45 nm. In other embodiments, the absorber layer 310 has a thickness in a range of about 10 nm to about 75 nm, including a range of about 20 nm to about 65 nm, and 30 nm to about 45 nm.

In one or more embodiments, the absorber layer comprises a dopant. In an embodiment, the dopant comprises oxygen. In an embodiment, the dopant is present in the compound in an amount in the range of about 0.1 wt. % to about 10 wt. %, based on the weight of the compound. In other embodiments, the dopant is present in the compound in an amount of about 0.1 wt. %, 0.2 wt. %, 0.3 wt. %, 0.4 wt. %, 0.5 wt. %, 0.6 wt. %, 0.7 wt. %. 0.8 wt. %, 0.9 wt. %, 1.0 wt. %, 1.1 wt. %, 1.2 wt. %, 1.3 wt. %, 1.4 wt. %, 1.5 wt. %, 1.6 wt. %, 1.7 wt. %. 1.8 wt. %, 1.9 wt. %, 2.0 wt. % 2.1 wt. %, 2.2 wt. %, 2.3 wt. %, 2.4 wt. %, 2.5 wt. %, 2.6 wt. %, 2.7 wt. %. 2.8 wt. %, 2.9 wt. %, 3.0 wt. %, 3.1 wt. %, 3.2 wt. %, 3.3 wt. %, 3.4 wt. %, 3.5 wt. %, 3.6 wt. %, 3.7 wt. %. 3.8 wt. %, 3.9 wt. %, 4.0 wt. %, 4.1 wt. %, 4.2 wt. %, 4.3 wt. %, 4.4 wt. %, 4.5 wt. %, 4.6 wt. %, 4.7 wt. %. 4.8 wt. %, 4.9 wt. %, or 5.0 wt. %.

In one or more embodiments, the compound of the absorber layer is a sputtered compound absorber material formed in a physical deposition chamber. In one or more embodiments, the compound of the absorber layer in some embodiments is sputtered by gases selected from one or more of argon (Ar), oxygen (O₂), or nitrogen (N₂). In an embodiment, the compound of the absorber layer in some embodiments is sputtered by a mixture of argon and oxygen gases (Ar+O₂). In some embodiments, sputtering by a mixture of argon and oxygen forms and oxide of the absorber layer material. In other embodiments, sputtering by a mixture of argon and oxygen does not form an oxide of the absorber layer material. In an embodiment, the compound of the absorber layer in some embodiments is sputtered by a mixture of argon and nitrogen gases (Ar+N₂). In some embodiments, sputtering by a mixture of argon and nitrogen forms a nitride of the absorber material. In other embodiments, sputtering with a mixture of argon and nitrogen does not form a nitride of the absorber material. In an embodiment, the compound of the absorber layer in some embodiments is sputtered by a mixture of argon and oxygen and nitrogen gases (Ar+O₂+N₂). In some embodiments, sputtering by a mixture of argon and oxygen and nitrogen forms an oxide and/or nitride of the absorber material. In other embodiments, sputtering by a mixture of argon and oxygen and nitrogen does not form an oxide or a nitride of the absorber material. In an embodiment, the etch properties and/or other properties of the absorber layer in some embodiments is tailored to specification by controlling the compound percentage(s), as discussed above. In an embodiment, the compound percentage(s) in some embodiments is precisely controlled by operating parameters such voltage, pressure, flow, etc., of the physical vapor deposition chamber. In an embodiment, a process gas is used to further modify the material properties, for example, N₂ gas is used to form nitrides of the absorber material.

In other embodiments, the compound of the absorber material in some embodiments is deposited layer by layer as a laminate of each component of the absorber material layers by forming a layer of a first component by sputtering. After deposition of the layer of the first component, the power the PVD chamber is turned off, and a flow of nitrogen gas or nitrogen and oxygen gas at a pressure of from 1-10 mT (e.g., 2 mT) for a period of time ranging from 1-10 s (e.g., 5 s) for one cycle. This process is referred to as gas phase nitridation of the first layer. The cycle of the first layer deposition by sputtering followed by nitrogen layer formation is repeated until the desired layer thickness is achieved.

In an embodiment, the absorber layer 310 is made from an alloy of two or more elements. In one or more embodiments, the alloy of the absorber layer is a co-sputtered alloy absorber material formed in a physical deposition chamber. In one or more embodiments, the alloy of the absorber layer can be co-sputtered by gases selected from one or more of argon (Ar), oxygen (O₂), or nitrogen (N₂). In an embodiment, the alloy of the absorber layer can be co-sputtered by a mixture of argon and oxygen gases (Ar+O₂). In some embodiments, co-sputtering by a mixture of argon and oxygen forms and oxide of the two elements. In other embodiments, co-sputtering by a mixture of argon and oxygen does not form an oxide of the two elements. In an embodiment, the alloy of the absorber layer can be co-sputtered by a mixture of argon and nitrogen gases (Ar+N₂). In some embodiments, co-sputtering by a mixture of argon and nitrogen forms a nitride of the two elements. In other embodiments, co-sputtering by a mixture of argon and nitrogen does not form a nitride of the two elements. In an embodiment, the alloy of the absorber layer can be co-sputtered by a mixture of argon and oxygen and nitrogen gases (Ar+O₂+N₂). In an embodiment, the etch properties and/or other properties of the absorber layer can be tailored to specification by controlling the alloy percentage(s), as discussed above. In an embodiment, the alloy percentage(s) can be precisely controlled by operating parameters such voltage, pressure, flow, etc., of the physical vapor deposition chamber. In an embodiment, a process gas is used to further modify the material properties, for example, N₂ gas is used to form nitrides of the absorber layer material.

In some embodiments, the hard mask material comprises Cr in a range of from about 63.9 wt. % to about 98.4 wt. %, oxygen in a range from about 1.6 wt. % to about 33.7 wt. % and nitrogen in a range of from 0 wt. % to about 9.3 wt. %.

In some embodiments, the hard mask material comprises Ta in a range of from about 75.5 wt. % to about 96.5 wt. % and Ni in a range of from about 3.5 wt. % to about 24.5 wt. %. In one or more embodiments in which the hard mask material comprises Ta and Ni, the hard mask material is doped with at least one of oxygen and nitrogen in a range of from 0.1 wt. % to 10 wt. %.

In some embodiments, the hard mask material comprises Ta in a range of from 0 wt. % to 72.9 wt. % and Ru in a range of from 0 wt. % to 27.1 wt. %, for example, Ta in a range of from about 0.2 wt. % to about 72.9 wt. % and Ru in a range of from about 27.1 wt. % to about 99.8 wt. %. A hard mask material comprising Ta and Ru of some embodiments is doped with at least one of oxygen and nitrogen in a range of from 0.1 wt. % to 10 wt. %.

In one or more embodiments, the hard mask material comprises Ta in a range of from about 60.5 wt. % to about 94.2 wt. % and Cu in a range of from about 5.8 wt. % to about 39.5 wt. %. In one or more embodiments in which the hard mask material comprises Ta and Cu, the hard mask material is doped with at least one of oxygen and nitrogen in a range of from 0.1 wt. % to 10 wt. %.

A specific embodiment pertains to an extreme ultraviolet (EUV) mask blank 302 comprising a substrate 304; a multilayer stack 306 which reflects EUV radiation, the multilayer stack 306 comprising a plurality of reflective layer pairs 316 including molybdenum (Mo) and silicon (Si); a capping layer 308 on the multilayer stack of reflecting layers; an absorber layer 310, the absorber layer 310 comprising an antimony-containing material selected from the group consisting of SbN, an alloy of carbon and antimony, and an alloy of tantalum and antimony; and a hard mask layer 318 on the absorber layer, the hard mask layer comprising a hard mask material selected from the group consisting of CrO, CrON, SiN, TaNi, TaRu and TaCu, wherein the hard mask layer 318 has an etch rate and the absorber layer 310 has an etch rate such that there is an etch selectivity of the hard mask layer 318 to the absorber layer 310 is in a range of from 5:1 to 30:1.

Specific, non-limiting examples of various combinations of an absorber layer 310 and a hard mask layer 318 will now be described. In one or more exemplary embodiments of the disclosure, relative etch rates using a Cl₂ etch chemistry of absorber layers to hard mask layers were compared in systems in which the thickness of the absorber layer ranges from 30 nm to 45 nm and the thickness of the hard mask layer ranges from 2 nm to 9 nm. For a CrON or CrO hard mask layer having the ranges described above and a TaSb absorber layer, etch rates were determined. For a CrO material, the etch rate ranged from 5 nm/min to 20 nm/min. For example, for a CrO material with an O content on a higher end of the 1.6-33.7 wt. % range, the etch rate was about 20 nm/min. When the O content was lowered to the lower end of the range, the etch rate was in a range of from about 5 nm/min to about 10 nm/min. For a CrON material having the ranges described above, the etch rate was in a range of from 20 nm/min to about 40 nm/min. When the nitrogen content was at the higher end of the 0-9.3 wt. % range, the etch rate increased to about the upper end of the range of 20 nm/min to about 40 nm/min. The TaSb absorber layer had an etch rate of in a range of about 100 nm/min to about 140 nm/min. The etch rate selectivity of the hard mask layer to the absorber layer was in a range of 3:30, for example 5:30.

In one or more exemplary embodiments of the disclosure, relative etch rates using a Cl₂ etch chemistry of absorber layers to hard mask layers were compared in systems in which the thickness of the absorber layer ranges from 30 nm to 45 nm and the thickness of the hard mask layer ranges from 2 nm to 9 nm. For a TaNi hard mask layer having the ranges described above and a TaSb absorber layer, etch rates were determined. For a TaNi material, the etch rate ranged from 20 nm/min to 80 nm/min. For example, for a TaNi material with an Ni content on a lower end of the 3.5-24.5 wt. % range, the etch rate was about 75 nm/min compared to a TaNi material with a higher amount of Ni, which had an etch rate of about 25 nm/min. The TaSb absorber layer had an etch rate of in a range of about 120 nm/min to about 140 nm/min. The etch rate selectivity of the hard mask layer to the absorber layer was in a range of 1.5:30, for example 5:30.

In one or more exemplary embodiments of the disclosure, relative etch rates using a CF₄ etch chemistry of absorber layers to hard mask layers were compared in systems in which the thickness of the absorber layer ranges from 30 nm to 45 nm and the thickness of the hard mask layer ranges from 2 nm to 9 nm. For a TaNi hard mask layer having the ranges described above and a TaSb absorber layer, etch rates were determined. For a TaNi material, the etch rate ranged from 5 nm/min to 250 nm/min. For example, for a TaNi material with an Ni content on a lower end of the 3.5-24.5 wt. % range, the etch rate was about 40 nm/min compared with a TaNi material with an Ni content on the higher end of the range having an etch rate of about 10 nm/min. The TaSb absorber layer had an etch rate of in a range of about 140 nm/min to about 160 nm/min. The etch rate selectivity of the hard mask layer to the absorber layer was in a range of 3:30, for example 5:30.

In one or more exemplary embodiments of the disclosure, relative etch rates using a Cl₂ etch chemistry of absorber layers to hard mask layers were compared in systems in which the thickness of the absorber layer ranges from 30 nm to 45 nm and the thickness of the hard mask layer ranges from 2 nm to 9 nm. For a TaRu hard mask layer having the ranges described above and a TaSb absorber layer, etch rates were determined. For a TaRu material, the etch rate ranged from 5 nm/min to 20 nm/min. For example, for a TaRu material with an Ru content on a higher end of the 27.1-100 wt. % range, the etch rate was about 5 nm/min. When the Ru content was lowered to the lower end of the 27.1-100 wt. % range, the etch rate was about 15 nm/min. The TaSb absorber layer had an etch rate of in a range of about 140 nm/min to about 160 nm/min. The etch rate selectivity of the hard mask layer to the absorber layer was in a range of 3:30, for example 5:30.

In exemplary embodiments of the disclosure, relative etch rates using a Cl₂ etch chemistry of absorber layers to hard mask layers were compared in systems in which the thickness of the absorber layer ranges from 30 nm to 45 nm and the thickness of the hard mask layer ranges from 2 nm to 9 nm. For a TaCu hard mask layer having the ranges described above and a TaSb absorber layer, etch rates were determined. For a TaCu material, the etch rate ranged from 1 nm/min to 10 nm/min. For example, for a TaCu material with a Cu content on a lower end of the 5.8-39.5 wt. % range, the etch rate ranged from 5 nm/min to 10 nm/min compared to a TaCu material having a Cu content on the higher end of the range, which had an etch rate of about 2 nm/min. The TaSb absorber layer had an etch rate of in a range of about 100 nm/min to about 140 nm/min. The etch rate selectivity of the hard mask layer to the absorber layer was in a range of from 1:25 to 1:30.

Still referring to FIG. 4, in a separate aspect of the disclosure that does not require the etch stop layer 309 shown in FIG. 4 or the specific materials discussed herein for the hard mask layer 118 or the etch stop layer 309, the EUV mask blank 302 comprises a trilayer 111 on the second side 304b of the substrate 304, the trilayer 311 including a first layer 303 on the second side 304b of the substrate 304, a second layer 305 on the first layer 303 and a third layer 307 on the second layer 305. In some embodiments, the EUV mask blank 302 comprises the trilayer 311 on the second side 304b of the substrate and the etch stop layer 309 and the hard mask layer 318 as described herein.

In one or more embodiments, the first layer 303 comprises a material which promotes adhesion of the trilayer to the second side of the substrate. In some embodiments, the second layer 305 comprises a material selected to reduce bowing of the substrate. In some embodiments, the third layer 307 comprises a material resistant to scratching. In one or more embodiments, the materials of the trilayer 111, in particular the second layer 305 achieves less than 200 nm of bow of the mask blank less than 100 nm of bow, or less than less than 50 nm of bow. Stated another way, the bow is in a range of from 0-200 nm, 0-100 nm or 0 50 nm. Thus, the second side 304b of the substrate 304 in some embodiments is compressively stressed to achieve <=50 nm bow on the back side of the mask. Selection of the particular materials depends on material conductivity meeting EUV mask blank chucking requirements. Hardness and scratch resistance should be as good as, if not better, than CrN. The materials of the trilayer 111 and in particular the third layer 307 should be resistant to etch and cleaning chemicals.

In one or more embodiments, the first layer 303 comprises a material selected from the group consisting of a transition metal, a transition metal oxide and a transition metal nitride. The transition metals of the first layer 303 according to one or more embodiments comprises combinations of two or more transition metals selected from Sc, Ti, V, Cr, Mn, Co, Ni, Cu, Zn, Y, Zr, Nb, Mo, Tc, Ru, Rh, Pd, Ag, Cd, La, Hf, Ta, W, Re, Os, Ir, Pt, Au, Hg, Ac, Rf, Db, Sg, Bh, Hs, Mt, Ds, Rg, and Cn. In specific embodiments, the transition metal of the first layer 303 comprises a combination of two or more transition metals selected from Cr, Ti, Ta, W, Zr, V, and Nb. In one or more embodiments, the first layer 303 has a thickness in a range of 1-50 nm, 1-40 nm, 1-30 nm, 1-20 nm, 5-50 nm, 5-40 nm, 5-30 nm, 5-20 nm, 10-50 nm, 10-40 nm, 10-30 nm, or 10-20 nm. In a specific embodiment the first layer 303 has a thickness in a range of 1-30 nm.

In one or more embodiments, the second layer 305 comprises a material selected from the group consisting of a transition metal nitride, a transition metal oxynitride, an aluminum-doped transition metal nitride, a transition metal alloy, an oxide of a transition metal alloy and a nitride of a transition metal alloy. The transition metals of the second layer 305 according to one or more embodiments comprises combinations of two or more transition metals selected from Sc, Ti, V, Cr, Mn, Co, Ni, Cu, Zn, Y, Zr, Nb, Mo, Tc, Ru, Rh, Pd, Ag, Cd, La, Hf, Ta, W, Re, Os, Ir, Pt, Au, Hg, Ac, Rf, Db, Sg, Bh, Hs, Mt, Ds, Rg, and Cn. In specific embodiments, the transition metal of the second layer 305 comprises a combination of two or more transition metals selected from Cr, Ti, Ta, W, Zr, V, and Nb. In one or more embodiments, the second layer 305 comprises a material selected from the group consisting of TaN, TiN, WN, ZrN, VN, NbN, TaOₓN_{y}, TiOₓN_{y}, WOₓN_{y}, ZrOₓN_{y}, VOₓN_{y}, NbOₓN_{y}, TaAlN, CrAlN, TiAlN, ZrAlN, CrTiAlN, CrTi, CrZr, TiV, CrV, and TaCr. In one or more embodiments, the second layer 305 has a thickness in a range of 1-70 nm, 1-60 nm, 1-50 nm, 1-40 nm, 1-30 nm, 1-20, nm, 5-70 nm, 5-60 nm, 5-50 nm, 5-40 nm, 5-30 nm, 5-20, nm, 10-70 nm, 10-60 nm, 10-50 nm, 10-40 nm, 10-30 nm, or 10-20, nm. In a specific embodiment, the second layer 305 has a thickness in a range of 1-60 nm.

In one or more embodiments, the third layer 307 comprises a material selected from the ground consisting of a transition metal nitride, an aluminum-doped transition metal nitride, a silicon-doped transition metal nitride and a boron-doped transition metal nitride. The transition metals of the third layer 307 according to one or more embodiments comprises combinations of two or more transition metals selected from Sc, Ti, V, Cr, Mn, Co, Ni, Cu, Zn, Y, Zr, Nb, Mo, Tc, Ru, Rh, Pd, Ag, Cd, La, Hf, Ta, W, Re, Os, Ir, Pt, Au, Hg, Ac, Rf, Db, Sg, Bh, Hs, Mt, Ds, Rg, and Cn. In specific embodiments, the transition metal of the third layer 307 comprises a combination of two or more transition metals selected from Cr, Ti, Ta, W, Zr, V, and Nb. In specific embodiments, the third layer 307 comprises a material selected from the group consisting of CrN, TiN, TaAlN, CrAlN, TiAlN, ZrAlN, CrTiAlN, CrSiN, CrAlSiN, TiSiN, CrBN, CrAlBN, and TiBN. In one or more embodiments, the first layer 303 has a thickness in a range of 1-50 nm, 1-40 nm, 1-30 nm, 1-20 nm, 5-50 nm, 5-40 nm, 5-30 nm, 5-20 nm, 10-50 nm, 10-40 nm, 10-30 nm, or 10-20 nm. In a specific embodiment the first layer 303 has a thickness in a range of 1-30 nm. In one or more embodiments, the third layer 307 has a thickness in a range of 1-50 nm, 1-40 nm, 1-30 nm, 1-20 nm, 5-50 nm, 5-40 nm, 5-30 nm, 5-20 nm, 10-50 nm, 10-40 nm, 10-30 nm, or 10-20 nm. In a specific embodiment the third layer 307 has a thickness in a range of 1-30 nm.

In one or more embodiments, the trilayer 311 comprises three layers of three different materials, for example: first layer 303/second layer 305/third layer 307 are: A/B/C, where A, B and C are each different materials from the other two materials in the trilayer. In other embodiments, the trilayer 311 comprises three layer of two different materials, for example: first layer 303/second layer 305/third layer 307 are: are A/B/A or A/B/B, or A/A/B where A and B are each different materials from the other material in the trilayer. In other embodiments, the trilayer 311 comprises three discrete layers of the same material, for example: first layer 303/second layer 305/third layer 307 are: A/A/A. In some embodiments, where the trilayer 311 comprises the same material in each of the layers, the deposition conditions may be adjusted so that density or another property of each layer is different from the other two layers in the trilayer. In embodiments in which each of layers of the trilayer comprises the same material, the material is selected from the group consisting of a transition metal, a transition metal oxide and a transition metal nitride, excluding CrN. The transition metals according to one or more embodiments comprises combinations of two or more transition metals selected from Sc, Ti, V, Cr, Mn, Co, Ni, Cu, Zn, Y, Zr, Nb, Mo, Tc, Ru, Rh, Pd, Ag, Cd, La, Hf, Ta, W, Re, Os, Ir, Pt, Au, Hg, Ac, Rf, Db, Sg, Bh, Hs, Mt, Ds, Rg, and Cn. In specific embodiments, the transition metal comprises a combination of two or more transition metals selected from Cr, Ti, Ta, W, Zr, V, and Nb.

The EUV mask blank in some embodiments is made in a physical deposition chamber having a first cathode comprising a first absorber material, a second cathode comprising a second absorber material, a third cathode comprising a third absorber material, a fourth cathode comprising a fourth absorber material, and a fifth cathode comprising a fifth absorber material, wherein the first absorber material, second absorber material, third absorber material, fourth absorber material and fifth absorber materials are different from each other, and each of the absorber materials have an extinction coefficient that is different from the other materials, and each of the absorber materials have an index of refraction that is different from the other absorber materials.

Another aspect of the disclosure pertains to a method of manufacturing an extreme ultraviolet (EUV) mask blank comprising forming on a first side 304a of substrate 304 a multilayer stack 306 which reflects EUV radiation, the multilayer stack 306 comprising a plurality of reflective layer pairs 316. The method further comprises forming a capping layer 308 on the multilayer stack 306 and forming an absorber layer 310 on the capping layer 308. The method further comprises forming on the second side 304b of the substrate 304 a trilayer 311 including a first layer 303 on the second side 304b of the substrate 304, a second layer 304 on the first layer 303 and a third layer 307 on the second layer 305.

The method of one or more embodiments further comprises forming a hard mask layer 318 on the absorber layer 310, the hard mask layer 318. Each of the respective layers of the method can comprise the properties materials described above with respect to FIG. 4.

In one or more embodiments, the method may further comprise etching the hard mask layer 318 and the absorber layer 310 at the respective etch rates disclosed herein. For example, the hard mask layer 318 in some embodiments has an etch rate and the absorber layer 310 has an etch rate such that there is an etch selectivity of the hard mask layer to the absorber layer is in a range of from 3:1 to 50:1, for example, from 5:1 to 30:1. In one or more embodiments, the hard mask layer 318 has a lower etch rate than absorber layer 310, and the etch selectivity of the hard mask layer 318 to the absorber layer 310 is in a range of from 3:1 to 50:1, for example, from 5:1 to 30:1, when the thickness of absorber layer is in a range of from 30 nm to 45 nm, and thickness of the hard mask layer 318 is in a range of from 2 nm to 9 nm.

In another embodiment, a method of manufacturing an extreme ultraviolet (EUV) mask blank 302 comprises forming on a first side 304a of a substrate 304 a multilayer stack 306 which reflects EUV radiation, the multilayer stack 306 comprising a plurality of reflective layer pairs 316, the substrate 304 including a second side 304b opposite the first side 304a, forming a capping layer 308 on the multilayer stack 306, forming an etch stop layer 309 on the capping layer 308, forming an absorber layer 310 on the etch stop layer 309, and forming a hard mask layer 318 on the absorber layer 310.

The EUV mask blank in some embodiments has any of the characteristics of the embodiments described above with respect to FIG. 4, and the method in some embodiments is performed in the system described with respect to FIG. 3.

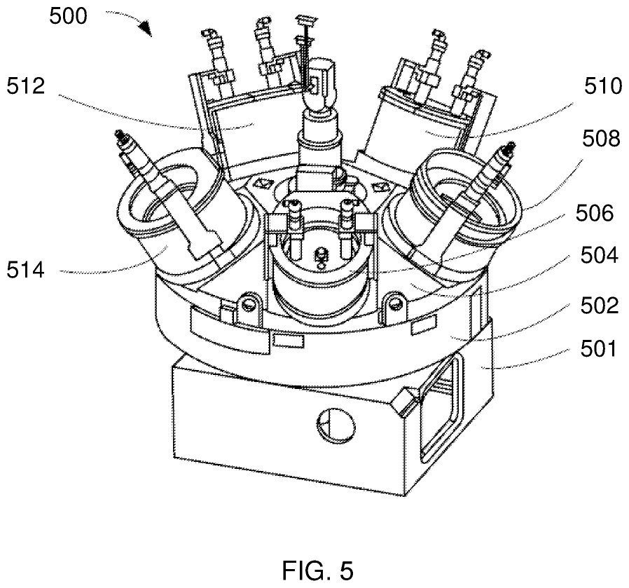

In another specific method embodiment, the different absorber layers are formed in a physical deposition chamber having a first cathode comprising a first absorber material and a second cathode comprising a second absorber material. Referring now to FIG. 5 an upper portion of a multi-cathode chamber 500 is shown in accordance with an embodiment. The multi-cathode chamber 500 includes a base structure 501 with a cylindrical body portion 502 capped by a top adapter 504. The top adapter 504 has provisions for a number of cathode sources, such as cathode sources 506, 508, 510, 512, and 514, positioned around the top adapter 504.

In one or more embodiments, the method forms an absorber layer that has a thickness in a range of 5 nm and 60 nm. In one or more embodiments, the materials used to form the absorber layer are selected to effect etch properties of the absorber layer. In one or more embodiments, the compound of the absorber layer is formed by sputtering a compound absorber material formed in a physical deposition chamber, which in some embodiments provides much thinner absorber layer thickness (less than 45 nm or less than 30 nm) and achieving less than 2% reflectivity and desired etch properties. In an embodiment, the etch properties and other desired properties of the absorber layer in some embodiments are tailored to specification by controlling the compound percentage of each absorber material. In an embodiment, the compound percentage in some embodiments is precisely controlled by operating parameters such voltage, pressure, flow etc., of the physical vapor deposition chamber.

The multi-cathode source chamber 500 in some embodiments is part of the system shown in FIG. 3. In an embodiment, an extreme ultraviolet (EUV) mask blank production system comprises a substrate handling vacuum chamber for creating a vacuum, a substrate handling platform, in the vacuum, for transporting a substrate loaded in the substrate handling vacuum chamber, and multiple sub-chambers, accessed by the substrate handling platform, for forming an EUV mask blank, including a multilayer stack of reflective layers on the substrate, the multilayer stack including a plurality of reflective layer pairs, a capping layer on the multilayer stack of reflective layers, and an absorber layer on the capping layer, the absorber layer made from a compound of antimony and nitrogen. The system in some embodiments is used to make the EUV mask blanks shown with respect to FIG. 4 and have any of the properties described with respect to the EUV mask blanks described with respect to FIG. 4 above.

Processes may generally be stored in the memory as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. An extreme ultraviolet (EUV) mask blank comprising:
a substrate including a first side and a second side opposite the first side;
a multilayer stack on the first side of the substrate which reflects EUV radiation, the multilayer stack comprising a plurality of reflective layer pairs;
a capping layer on the multilayer stack;
an absorber layer on the capping layer; and
a trilayer on the second side of the substrate, the trilayer including a first layer on the second side of the substrate, a second layer on the first layer and a third layer on the second layer.

2. The extreme ultraviolet (EUV) mask blank of claim 1, wherein the first layer comprises a material which promotes adhesion of the trilayer to the second side of the substrate and the second layer comprises a material selected to reduce bowing of the substrate.

3. The extreme ultraviolet (EUV) mask blank of claim 2, wherein the third layer comprises a material resistant to scratching.

4. The extreme ultraviolet (EUV) mask blank of claim 2, wherein the first layer comprises a material selected from the group consisting of a transition metal, a transition metal oxide and a transition metal nitride.

5. The extreme ultraviolet (EUV) mask blank of claim 4, wherein the transition metal comprises a material selected from the group consisting of Cr, Ti, Ta, W, Zr, V, and Nb.

6. The extreme ultraviolet (EUV) mask blank of claim 2, wherein the second layer comprises a material selected from the group consisting of a transition metal nitride, a transition metal oxynitride, an aluminum-doped transition metal nitride, a transition metal alloy, an oxide of a transition metal alloy and a nitride of a transition metal alloy.

7. The extreme ultraviolet (EUV) mask blank of claim 6, wherein the second layer comprises a material selected from the group consisting of Ta, TaN, TiN, WN, ZrN, VN, NbN, TaOₓN_{y}, TiOₓN_{y}, WOₓN_{y}, ZrOₓN_{y}, VOₓN_{y}, NbOₓN_{y}, TaAlN, CrAlN, TiAlN, ZrAlN, CrTiAlN, CrTi, CrZr, TiV, CrV, and TaCr.

8. The extreme ultraviolet (EUV) mask blank of claim 3, wherein the third layer comprises a material selected from the group consisting of a transition metal nitride, an aluminum-doped transition metal nitride, a silicon-doped transition metal nitride and a boron-doped transition metal nitride.

9. The extreme ultraviolet (EUV) mask blank of claim 8, wherein the third layer comprises a material selected from the group consisting of CrN, TiN, TaAlN, CrAlN, TiAlN, ZrAlN, CrTiAlN, CrSiN, CrAlSiN, TiSiN, CrBN, CrAlBN, and TiBN.

10. The extreme ultraviolet (EUV) mask blank of claim 1, wherein the absorber layer comprises a material selected from the group consisting of TaSb, TaCu, TaRu, TaRuSb, TaNi, TaIr, TaIrSb, TaPt, TaMo, TaNb, TaPd, TeGeSbC, SbN, RuSb, IrSb, CSb, SbTe, SbPt, SbNb, SbPd, MoN, MoPt, MoNb, TeGe, BiFe, BNi, CuHf, IrAl, IrMo, TeNi, TeAl, TeCu, TeFe, RuMo, RuSi, RuIr, TaRuIr, RuN, RuPd, RuPt, RuNb, NbPd and oxides and nitrides thereof.

11. The extreme ultraviolet (EUV) mask blank of claim 1, further comprising an etch stop layer on the capping layer and beneath the absorber layer, the etch stop layer comprising a material selected from the group consisting of CrN, CrₓO_{y}N_{z}, SiₓN_{y}, TaNi, TaRu, and TaCu.

12. The extreme ultraviolet (EUV) mask blank of claim 1, further comprising a hard mask layer on the absorber layer, the hard mask layer comprising a material selected from the group consisting of CrN, CrₓO_{y}N_{z}, SiₓN_{y}, TaNi, TaRu, and TaCu.

13. A method of manufacturing an extreme ultraviolet (EUV) mask blank comprising:
forming on a first side of a substrate a multilayer stack which reflects EUV radiation, the multilayer stack comprising a plurality of reflective layer pairs, the substrate including a second side opposite the first side;
forming a capping layer on the multilayer stack;
forming an absorber layer on the capping layer; and
forming on the second side of the substrate a trilayer including a first layer on the second side of the substrate, a second layer on the first layer and a third layer on the second layer.

14. The method of claim 13, wherein the first layer comprises a material which promotes adhesion of the trilayer to the second side of the substrate and the second layer comprises a material selected to reduce bowing of the substrate.

15. The method of claim 14, wherein the third layer comprises a material resistant to scratching.

16. The method of claim 13, wherein the first layer comprises a material selected from a transition metal, a transition metal oxide and a transition metal nitride.

17. The method of claim 16, wherein the transition metal comprises a material selected from the group consisting of Cr, Ti, Ta, W, Zr, V, and Nb.

18. The method of claim 14, wherein the second layer comprises a transition metal nitride, a transition metal oxynitride, an aluminum-doped transition metal nitride, a transition metal alloy, an oxides of a transition metal alloy and a nitride of a transition metal alloy.

19. The method of claim 18, wherein the second layer comprises a material selected from the group consisting of Ta, TaN, TiN, WN, ZrN, VN, NbN, TaOₓN_{y}, TiOₓN_{y}, WOₓN_{y}, ZrOₓN_{y}, VOₓN_{y}, NbOₓN_{y}, TaAlN, CrAlN, TiAlN, ZrAlN, CrTiAlN, CrTi, CrZr, TiV, CrV, and TaCr.

20. The method of claim 15, wherein the third layer comprises a material selected from the group consisting of transition metal nitride, an aluminum-doped transition metal nitride, a silicon-doped transition metal nitride and a boron-doped transition metal nitride.

21. The method of claim 20, wherein the third layer comprises a material selected from the group consisting of CrN, TiN, TaAlN, CrAlN, TiAlN, ZrAlN, CrTiAlN, CrSiN, CrAlSiN, TiSiN, CrBN, CrAlBN, and TiBN.

22. The method of claim 16, wherein the absorber layer comprises a material selected from the group consisting of TaSb, TaCu, TaRu, TaRuSb, TaNi, TaIr, TaIrSb, TaPt, TaMo, TaNb, TaPd, TeGeSbC, SbN, RuSb, IrSb, CSb, SbTe, SbPt, SbNb, SbPd, MoN, MoPt, MoNb, TeGe, BiFe, BNi, CuHf, IrAl, IrMo, TeNi, TeAl, TeCu, TeFe, RuMo, RuSi, RuIr, TaRuIr, RuN, RuPd, RuPt, RuNb, NbPd and oxides and nitrides thereof.

23. The method of claim 12, further comprising forming an etch stop layer on the capping layer and beneath the absorber layer, the etch stop layer selected from the group consisting of CrN, CrₓO_{y}N_{z}, SiₓN_{y}, TaNi, TaRu, and TaCu.

24. The method of claim 12, further comprising forming a hard mask layer on the absorber layer, the hard mask layer selected from the group consisting of CrN, CrₓO_{y}N_{z}, SiₓN_{y}, TaNi, TaRu, and TaCu.
